(19) United States
(12) Patent Application Publication
(10) Pub. No.: US 2015/0171150 A1
(43) Pub. Date: Jun. 18, 2015

(54) MANUFACTURING METHOD OF ORGANIC LIGHT EMITTING DIODE DISPLAY DEVICE

(71) Applicant: Samsung Display Co., Ltd., Hwaseong-si (KR)

(72) Inventor: Nam HA, Hwaseong-si (KR)

(21) Appl. No.: 14/327,111

(22) Filed: Jul. 9, 2014

(30) Foreign Application Priority Data
Dec. 18, 2013 (KR) 10-2013-0158197

(51) Int. Cl. H01L 27/32; H01L 51/00; H01L 51/56

(52) U.S. Cl. CPC H01L 27/3246; H01L 51/56; H01L 51/0002; H01L 51/0021; H01L 51/5088

(57) ABSTRACT

A manufacturing method of an organic light emitting diode display device includes: forming a gate electrode on a display area of a substrate including a peripheral area; forming a gate insulating layer on the substrate; forming a semiconductor layer overlapping the gate electrode; forming source and drain electrodes on the semiconductor layer; forming a passivation layer on the source and drain electrodes, and the gate insulating layer; forming a first electrode connected to the drain electrode; forming an etching preventing layer on the gate insulating layer in the peripheral area; forming a pixel definition layer including an opening exposing the first electrode; forming a first organic layer in the opening and a second organic layer on the pixel definition layer and the etching preventing layer; removing the second organic layer on the etching prevention layer; removing the etching prevention layer; and forming a second electrode on the second organic layer.

### CROSS-REFERENCE TO RELATED APPLICATION

This application claims priority to and the benefit of Korean Patent Application No. 10-2013-0158197 filed on Dec. 18, 2013, which is hereby incorporated by reference for all purposes as if fully set forth herein.

### BACKGROUND

1. Field

Exemplary embodiments of the present invention relate to a manufacturing method of an organic light emitting diode display device.

2. Discussion of the Background

An organic light emitting diode display device includes a display substrate including a display area for displaying an image and a peripheral area, and an encapsulation substrate formed on the display substrate for sealing it.

A plurality of light emitting diodes are provided to form pixels in the display area, and the organic light emitting diode includes an anode, a cathode, and a plurality of organic layers including organic emission layers formed between the anode and the cathode.

The peripheral area is formed with a sealant for bonding the display substrate and the encapsulation substrate, and a moisture absorbent for removing moisture.

As a substrate size becomes larger, one mask cannot cover the entire display substrate when forming organic layers. Thus, masks for forming each organic layer are sequentially arranged, such that the display substrate is moved above these masks through which organic layer forming materials are transmitted, thereby forming the organic layers.

In this case, as the peripheral area is also formed with the organic layers, which are not easily bonded to the sealant and the moisture absorbent, the organic layer and the sealant should be formed, after removing the organic layer, on an inorganic layer disposed below the organic layer.

However, when removing the organic layers, there is a problem that the inorganic layer disposed below the organic layers is partially removed.

The above information disclosed in this Background section is only for enhancement of understanding of the background of the invention and therefore it may contain information that does not form the prior art that is already known in this country to a person of ordinary skill in the art.

### SUMMARY

Exemplary embodiments of the present invention provide a manufacturing method of an organic light emitting diode display device for uniformly forming a surface of an inorganic layer in a peripheral area.

Additional features of the invention will be set forth in the description which follows, and in part will be apparent from the description, or may be learned by practice of the invention.

A manufacturing method of an organic light emitting diode display device according to an exemplary embodiment of the present invention includes: forming a gate electrode in a display area on a substrate including a peripheral area surrounding the display area; forming a gate insulating layer by an inorganic insulating material on the gate electrode and the substrate; forming a semiconductor layer overlapping the gate electrode on the gate insulating layer in the display area; forming source and drain electrodes on the semiconductor layer; forming a passivation layer on the source electrode, the drain electrode, and the gate insulating layer; forming a first electrode on the passivation layer and connected to the drain electrode; forming an etching preventing layer on the gate insulating layer in the peripheral area; forming a pixel definition layer on the passivation layer and including an opening exposing the first electrode; forming a first organic layer on the first electrode in the opening and a second organic layer on the pixel definition layer and the etching preventing layer; removing the second organic layer from the etching prevention layer; removing the etching prevention layer; and forming a second electrode on the second organic layer.

As described above, according to an exemplary embodiment of the present invention, when removing the organic layers in the peripheral area, the inorganic layer may be prevented from being partially removed by forming the etching preventing layer on the inorganic layer.

Accordingly, spaces between the sealant and the inorganic layer and the moisture absorbent are not formed such that bonding between them can be easily performed, thereby preventing external moisture and foreign particles from permeating into the display area.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a schematic top plan view of an organic light emitting diode display device according to an exemplary embodiment of the present invention.

FIG. 2 is an enlarged top plan view of an A portion of FIG. 1

FIG. 3 is a cross-sectional view of FIG. 2 taken along the line III-III.

FIGS. 4 to 6 and FIGS. 8 to 12 are cross-sectional views sequentially illustrating a manufacturing method of an organic light emitting diode display device according to an exemplary embodiment of the present invention.

FIG. 7 is a drawing of masks for forming an organic layer according to the exemplary embodiment of the present invention.

### DETAILED DESCRIPTION OF THE EMBODIMENTS

The present invention will be described more fully hereinafter with reference to the accompanying drawings, in which exemplary embodiments of the invention are shown.

As those skilled in the art would realize, the described embodiments may be modified in various different ways, all without departing from the spirit or scope of the present invention. On the contrary, exemplary embodiments introduced herein are provided to make disclosed contents thorough and complete, and to sufficiently transfer the spirit of the present invention to those skilled in the art.

In addition, the size and thickness of each configuration shown in the drawings are arbitrarily shown for better understanding and ease of description, but the present invention is not limited thereto. In the drawings, the thickness of layers, films, panels, regions, etc. are exaggerated for clarity. In the drawings, for better understanding and ease of description, the thickness of some layers and areas is exaggerated.

It will be understood that when an element such as a layer, film, region, or substrate is referred to as being “on” another element, it can be directly on the other element or intervening elements may also be present. It will be understood that for the purposes of this disclosure, “at least one of X, Y, and Z” can be construed as X only, Y only, Z only, or any combination of two or more items X, Y, and Z (e.g., XYZ, XYY, YZ, ZZ).

In addition, unless explicitly described to the contrary, the word “comprise” and variations such as “comprises” or “comprising” will be understood to imply the inclusion of stated elements but not the exclusion of any other elements. Further, in the specification, the phrase “on a plane” means viewing the object portion from the top, and the phrase “on a cross-section” means viewing a cross-section of which the object portion is vertically cut from the side.

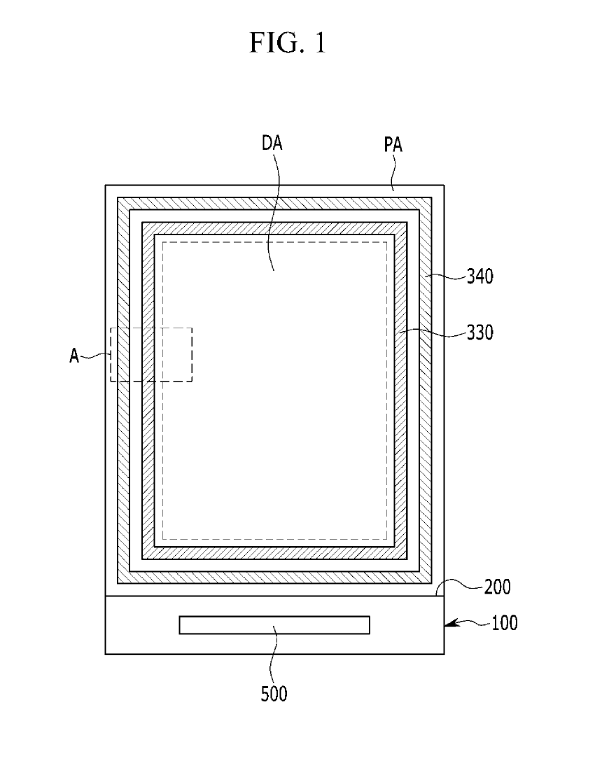

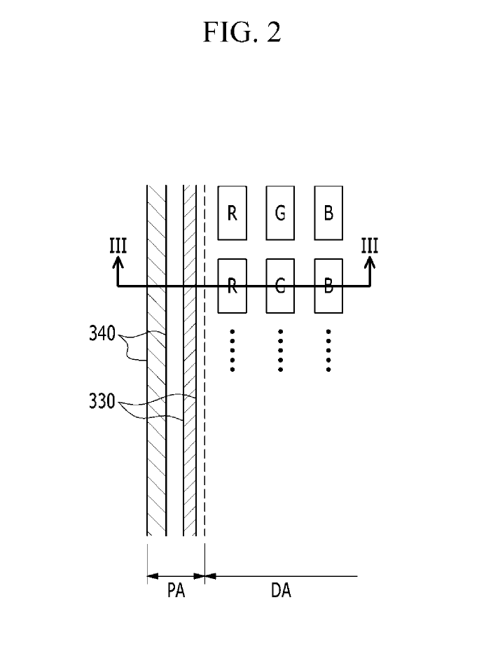

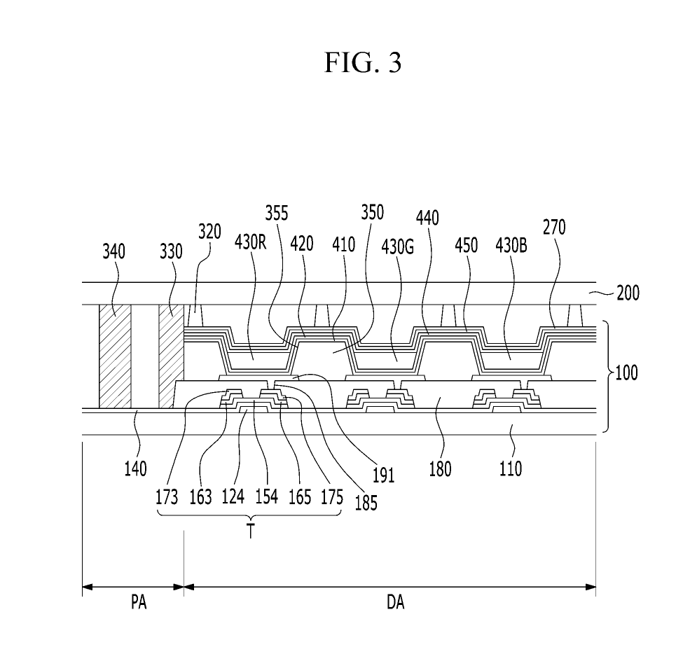

FIG. 1 is a schematic top plan view of an organic light emitting diode display device according to an exemplary embodiment of the present invention, FIG. 2 is an enlarged top plan view of an A portion of FIG. 1, and FIG. 3 is a cross-sectional view of FIG. 2 taken along the line III-III. Referring to FIGS. 1 to 3, the organic light emitting diode display device includes a display substrate 100, and an encapsulation substrate 200 facing the display substrate 100.

The display substrate 100 includes a plurality of thin film layers that are disposed on a substrate 110 and are made of transparent glass or plastic. The display substrate 100 is divided into a display area DA for displaying an image and a peripheral area surrounding the display area DA. A plurality of pixels including red pixels, blue pixels, and green pixels are disposed in the display area DA.

Each pixel is provided with a first electrode 191, a second electrode 270, an organic light emitting diode including organic emission layers 430R, 430G, and 430B disposed between the first and second electrodes 191 and 270, and a driving thin film transistor T connected to the organic light emitting diode. Although not illustrated, scan lines and data lines connected to the driving thin film transistor T are further provided.

The peripheral area PA is provided with a driving unit 500, so as to process signals supplied from an external source and then supply the processed signals to the scan lines and the data lines of the display area DA. The driving unit 500 converts the signals supplied from the external source into scan signals and data signals, to selectively drive each pixel.

The peripheral area PA is further provided with a sealant 340 for bonding the display substrate 100 and the encapsulation substrate 200 which are disposed along a circumference of the display area DA, and a moisture absorbent 330 for preventing moisture permeation into the display area DA.

The moisture absorbent 330 is disposed between the sealant 340 and the display area DA. The moisture absorbent 330 contains a frit glass or a glass paste.

A detailed structure of the organic light emitting diode display device according to the exemplary embodiment will be described hereinafter according to a laminating sequence. First, the display substrate 100 will be described.

Gate electrodes 124 are disposed on the substrate 110 in the display area DA. Each of the gate electrodes 124 is connected to a scan line.

A gate insulating layer 140 is disposed on the gate electrodes 124 and the substrate 110. The gate insulating layer 140 is made of an inorganic insulating material such as a silicon oxide (SiOₓ) or a silicon nitride (SiNₓ).

Semiconductor layers 154 are disposed on the gate insulating layer 140 in the display area DA. A semiconductor layer 154 overlaps each of the gate electrodes 124.

Ohmic contact layers 163 and 165 are disposed on each of the semiconductor layers 154, and source and drain electrodes 173 and 175 are respectively disposed on the ohmic contact layers 163 and 165. The ohmic contact layers 163 and 165 and the source and drain electrodes 173 and 175 partially expose the semiconductor layer 154. The ohmic contact layers 163 and 165 are disposed between the semiconductor layer 154 and the source electrode 173, and between the semiconductor layer 154 and the drain electrode 175, to lower contact resistance therebetween.

The source and drain electrodes 173 and 175 face each other based on the gate electrode 124. The gate electrode 124, the source electrode 173, and the drain electrode 175 form a thin film transistor T together with the semiconductor layer 154, and a channel of the thin film transistor T is formed in the semiconductor layer 154 between the source and drain electrodes 173 and 175.

A passivation layer 180 is disposed on the source electrode 173, the drain electrode 175, and the gate insulating layer 140 in the display area DA. A contact hole 185 partially exposing each of the drain electrodes 175 is formed in the passivation layer 180.

First electrodes 191 are disposed on the passivation layer 180 and in the display area DA. A first electrode 191 is connected to each of the drain electrodes 175 through the contact hole 185.

A pixel definition layer 350 is disposed on edges of the first electrode 191 and on the passivation layer 180. The pixel definition layer 350 is formed with an opening 355 to expose each of the first electrodes 191.

A hole injection layer 410 and a hole transporting layer 420 are sequentially disposed on the first electrode 191, in the opening 355, and on the pixel definition layer 350. Emission layers 430R, 430G, and 430B are disposed on the hole transporting layer 420 in the opening 355.

An electron transporting layer 440 and an electron injection layer 450 are sequentially disposed on the emission layers 430R, 430G, and 430B and the hole transporting layer 420. A second electrode 270 is disposed on the electron injection layer 450.

The first electrode 191, the second electrode 270, the hole injection layer 410 disposed between the first and second electrodes 191 and 270, the hole transporting layer 420, the emission layers 430R, 430G, and 430B, the electron transporting layer 440, and the electron injection layer 450 form the organic light emitting diode. The first electrode 191 becomes an anode as the hole injection electrode, and the second electrode 270 becomes a cathode as the electron injection electrode. However, the present exemplary embodiment is not necessarily limited thereto, and depending on a driving method of the organic light emitting diode display device, the first electrode 191 may become the cathode while the second electrode 270 may become the anode.

Holes and electrons are injected into the emission layers 430R, 430G, and 430B from the pixel electrode 191 and the common electrode 270, respectively. Exitons generated by coupling the injected holes and electrons fall from an excited state to a ground state, to emit light.

The hole injection layer 410, the hole transporting layer 420, the emission layers 430R, 430G, and 430B, the electron transporting layer 440, and the electron injection layer 450 may be made of a low-molecular weight organic material or high-molecular weight organic material.

The hole injection layer 410 and the hole transporting layer 420 enable the holes to be easily injected into the emission layers 430R, 430G, and 430B. The electron transporting layer 440 and the electron injection layer 450 enable the electrons to be easily injected into the emission layers 430R, 430G, and 430B.

The first electrode 191 is made of a transparent conductive material such as indium tin oxide (ITO) or indium zinc oxide (IZO), and the second electrode 270 is made of a reflective metal such as lithium (Li), calcium (Ca), lithium fluoride/calcium (LiF/Ca), lithium fluoride/aluminum (LiF/Al), aluminum (Al), silver (Ag), magnesium (Mg), or gold (Au). However, the present exemplary embodiment is not necessarily limited thereto, and the first electrode 191 may be made of a reflective metal, while the second electrode 270 may be made of a transparent conductive material.

Further, the present exemplary embodiment is provided with the hole injection layer 410, the hole transporting layer 420, the electron transporting layer 440, and the electron injection layer 450, but it is not limited thereto. For example, one or more of these layers may be omitted.

The encapsulation substrate 200 is disposed on the display substrate 100. The encapsulation substrate 200 and the display substrate 100 are spaced apart by a spacer 320. The spacer 320 is disposed in the display area DA at a position corresponding to the pixel defining layer 350, on the electron injection layer 450.

The sealant 340 is disposed in the peripheral area PA to bond the display substrate 100 and the encapsulation substrate 200. The moisture absorbent 330 is disposed in the peripheral area PA to contact the display substrate 100 and the encapsulation substrate 200. Herein, the sealant 340 and the moisture absorbent 330 contact the gate insulating layer 140 made of an inorganic insulating material.

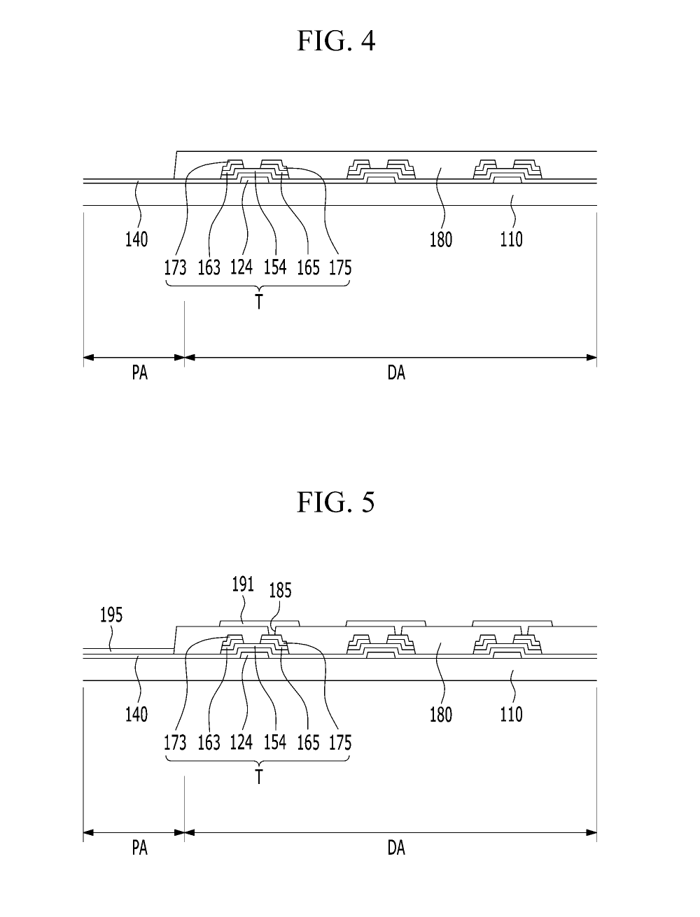

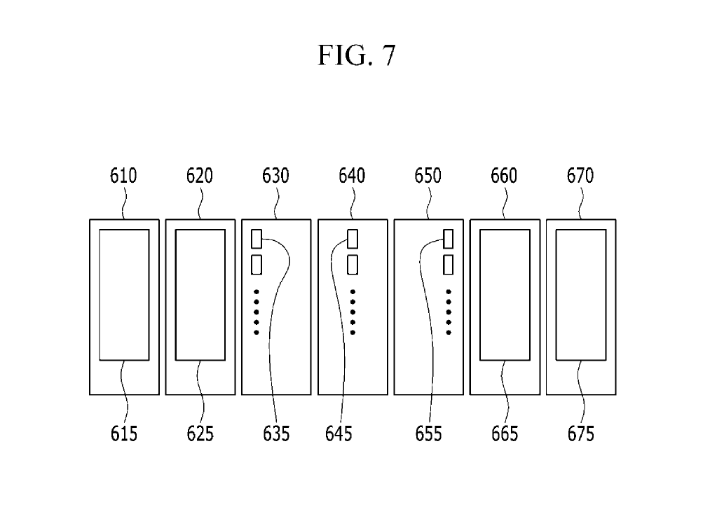

A manufacturing method of an organic light emitting diode display device, according to an exemplary embodiment of the present invention, will be described hereinafter with reference to FIGS. 4 to 12 and FIG. 3. FIGS. 4 to 6 and FIGS. 8 to 12 are cross-sectional views sequentially illustrating the manufacturing method of the organic light emitting diode display device according to the exemplary embodiment of the present invention, and FIG. 7 is a drawing of masks for forming an organic layer according to the exemplary embodiment of the present invention.

Referring to FIG. 4, gate electrodes 124 are formed on a substrate 110 including a display area DA for displaying an image and a peripheral area PA surrounding the display area DA. A gate insulating layer 140 is then formed on the gate electrodes 124 and the substrate 110. The gate electrode 124 is formed in the display area DA, and the gate insulating layer 140 is formed of an inorganic insulating material such as a silicon oxide (SiOₓ) or a silicon nitride (SiNₓ)

Next, semiconductor layers 154 are formed on the gate insulating layer 140 and in the display area DA. Ohmic contact layers 163 and 165, a source electrode 173, and a drain electrode 175 are sequentially formed on each of the semiconductor layers 154. A semiconductor layer 154 overlaps each of the gate electrodes 124. Next, a passivation layer 180 is formed on the source electrode 173, the drain electrode 175, and the gate insulating layer 140, in the display area DA.

Referring to FIG. 5, after a contact hole 185 partially exposing the drain electrode 185 is formed in the passivation layer 180, first electrodes 191 are formed on the passivation layer 180. An etching preventing layer 195 is formed on the gate insulating layer 140 in the peripheral area PA.

A first electrode 191 is connected to each of the drain electrodes 175 through the contact hole 185. The etching preventing layer 195 is formed of the same material as the first electrode 191. That is, the etching preventing layer 195 and the first electrode 191 may be simultaneously formed. In addition, the etching preventing layer 195 may be formed of a different metallic material from the first electrode 191. In this case, the etching preventing layer 195 and the first electrode 191 may not simultaneously formed. For example, the etching preventing layer 195 may be formed first, or the first electrode 191 may be formed first.

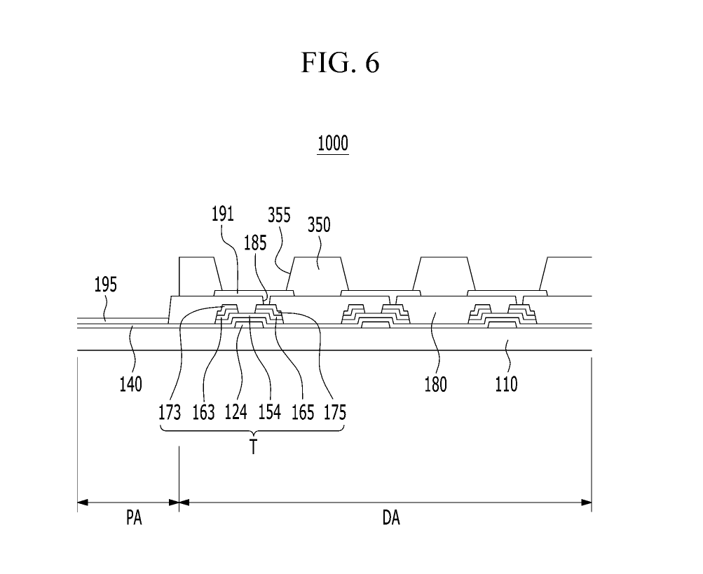

Referring to FIG. 6, a pixel definition layer 350 is formed on edges of the first electrode 191 and on the passivation layer 180. The pixel definition layer 350 includes an opening 355 exposing the first electrode 191. The substrate 110 laminated to the pixel definition layer 350 is referred to as a target substrate 1000 in the present exemplary embodiment.

Next, organic layers are formed on the target substrate 1000, and a mask is prepared for this purpose. Herein, the organic layers refers to a hole injection layer 410, a hole transporting layer 420, emission layers 430R, 430G, and 430B, an electron transporting layer 440, and an electron injection layer 450.

The mask will now be described with reference to FIG. 7. Referring to FIG. 7, the mask for forming the organic layers according to the present exemplary embodiment include first, second, third, fourth, fifth, sixth, and seventh masks 610, 620, 630, 640, 650, 660, and 670.

The first, second, sixth, and seventh masks 610, 620, 660, and 670 respectively include first, second, sixth, and seventh transmissive portions 615, 625, 665, and 675 through which organic materials are transmitted. Herein, the first, second, sixth, and seventh transmissive portions 615, 625, 665, and 675 are located at the same position.

The third, fourth, and fifth masks 630, 640, and 650 respectively include third, fourth, and fifth transmissive portions 635, 645, and 655 through which the organic materials are transmitted. Herein, the third, fourth, and fifth transmissive portions 635, 645, and 655 are respectively located at different positions. In addition, the third, fourth, and fifth transmissive portions 635, 645, and 655 are respectively located at different positions from the first transmissive portion 615.

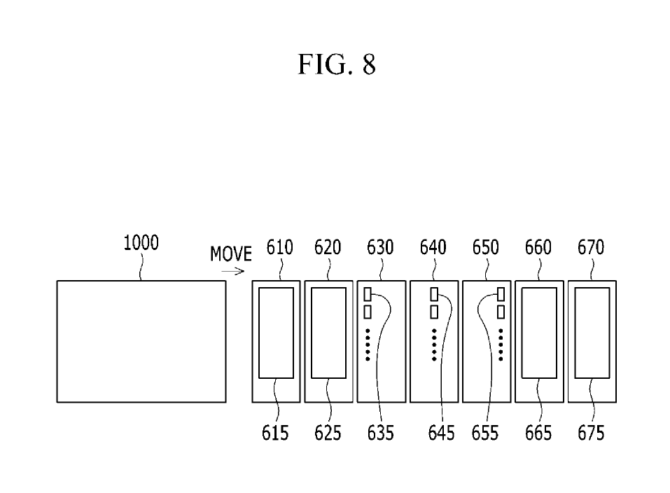

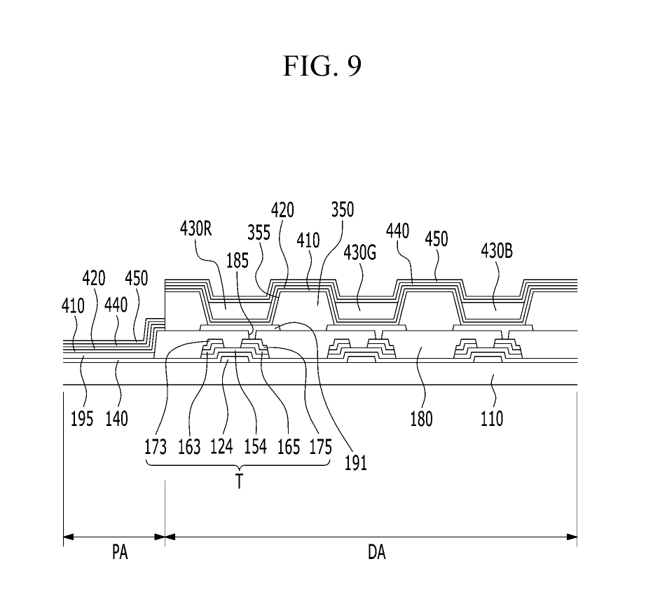

A forming method of organic layers using the mask for forming an organic layer according to the present exemplary embodiment will now be described with reference to FIGS. 8 and 9. Referring to FIG. 8, the target substrate 1000 is moved to face the first, second, third, fourth, fifth, sixth, and seventh masks 610, 620, 630, 640, 650, 660, and 670, which are sequentially arranged.

Each of the masks 610, 620, 630, 640, 650, 660, and 670 is unable to cover the entire target substrate 1000 as the target substrate 1000 is larger than the respective masks. Thus, each of the masks 610, 620, 630, 640, 650, 660, and 670 are sequentially arranged, such that the target substrate 1000 is moved with respect to the masks to form the organic layers.

The first mask 610 transmits a material for forming the hole injection layer 410 through the first transmissive portion 615. The second mask 620 transmits a material for forming the hole transporting layer 420 through the second transmissive portion 625.

The third, fourth, and fifth masks 630, 640, and 650 respectively transmit materials for forming the emission layers 430R, 430G, and 430B through the third, fourth, and fifth transmissive portions 635, 645, and 655.

The sixth mask 660 transmits a material for forming the electron transporting layer 440 through the sixth transmissive portion 665, and the seventh mask 670 transmits a material for forming the electron injection layer 450 through the seventh transmissive portion 675. That is, as the target substrate 100 is sequentially moved with respect to the first, second, third, fourth, fifth, sixth, and seventh masks 610, 620, 630, 640, 650, 660, and 670, the organic layers are formed on the target substrate 1000.

Herein, the forming materials for forming the hole injection layer 410, the hole transporting layer 420, the emission layers 430R, 430G, and 430B, the electron transporting layer 440, and the electron injection layer 450 may be a low-molecular weight organic material or high-molecular weight organic material.

Referring to FIG. 9, after the target substrate 100 is sequentially moved above the first, second, third, fourth, fifth, sixth, and seventh masks 610, 620, 630, 640, 650, 660, and 670, the hole injection layer 410, the hole transporting layer 420, the emission layers 430R, 430G, and 430B, the electron transporting layer 440, and the electron injection layer 450 are formed in the display area DA, while the hole injection layer 410, the hole transporting layer 420, the electron transporting layer 440, and the electron injection layer 450 are formed in the peripheral area PA.

In more detail, the hole injection layer 410 and the hole transporting layer 420 are sequentially formed on the portion of the first electrode 191 exposed by the pixel definition layer 350, and the opening 355, the emission layers 430R, 430G, and 430B are respectively formed on the hole transporting layer 420 in the opening 355. The electron transporting layer 440 and the electron injection layer 450 are sequentially formed on the emission layers 430R, 430G, and 430B and the hole transporting layer 420. The hole injection layer 410, the hole transporting layer 420, the electron transporting layer 440, and the electron injection layer 450 are sequentially formed on the etching preventing layer 195 in the peripheral area PA.

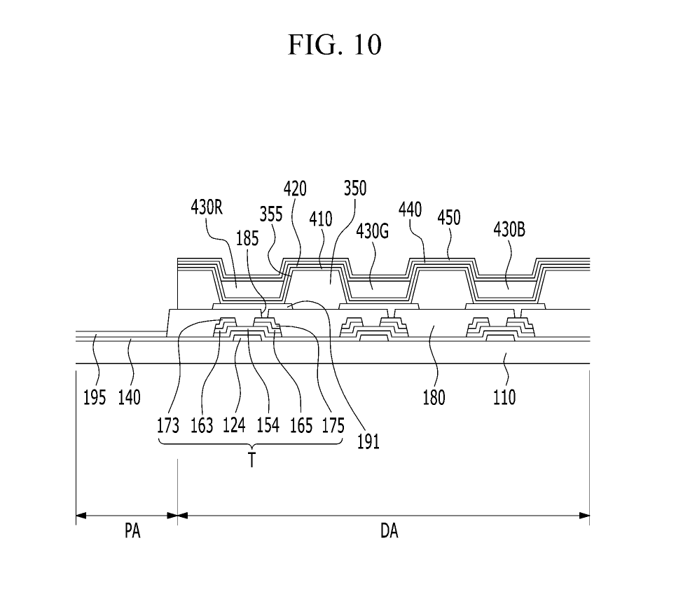

Referring to FIG. 10, the organic layers, that is, the hole injection layer 410, the hole transporting layer 420, the electron transporting layer 440, and the electron injection layer 450, are removed from the peripheral area PA. The hole injection layer 410, the hole transporting layer 420, the electron transporting layer 440, and the electron injection layer 450 may be removed by using plasma. The hole injection layer 410, the hole transporting layer 420, the electron transporting layer 440, and the electron injection layer 450 may be removed by isotropic etching utilizing radicals generated by injecting nitrogen trifluoride (NF₃), oxygen (O₂), and argon (Ar) into a plasma source.

When removing the portions of the hole injection layer 410, the hole transporting layer 420, the electron transporting layer 440, and the electron injection layer 450 that are formed on the gate insulating layer 140, without using a conventional etching preventing layer 195, a surface of the gate insulating layer 140 may be non-uniformly formed, as the gate insulating layer 140 is also partially etched. In this case, spaces are formed between the sealant 340 and gate insulating layer 140 and between the moisture absorbent 330 and the gate insulating layer 140, such that moisture and foreign particles may permeate into the display area DA through these spaces to cause defects.

In the present exemplary embodiment, since the etching preventing layer 195 is formed on the gate insulating layer 140, it prevents the gate insulating layer 140 from being partially removed, when removing the hole injection layer 410, the hole transporting layer 420, the electron transporting layer 440, and the electron injection layer 450. That is, the surface of the gate insulating layer 140 is uniformly maintained.

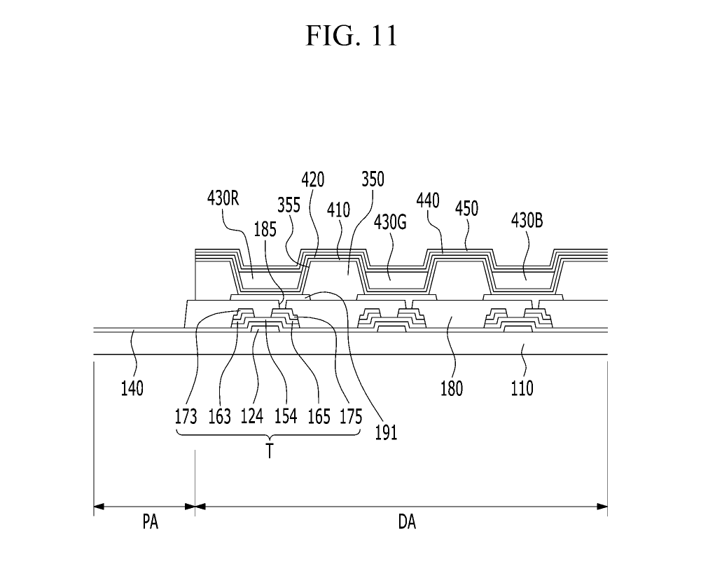

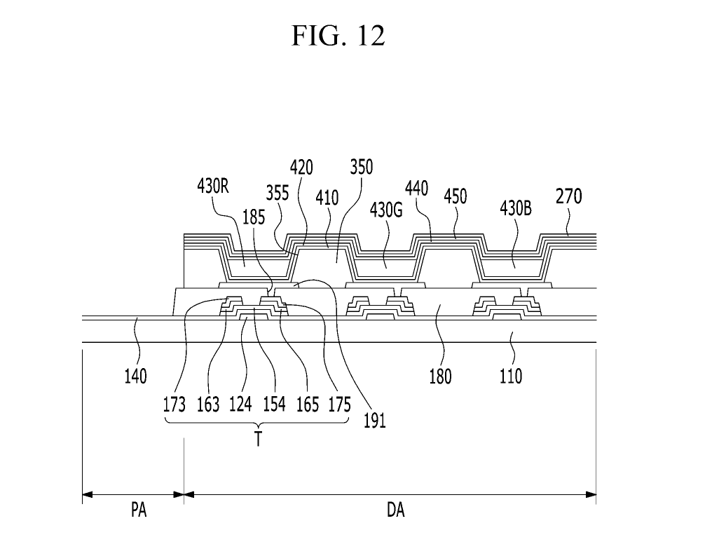

Referring to FIGS. 11 and 12, after removing the etching preventing layer 195 formed in the peripheral area PA, the second electrode 270 is formed on the electron injection layer 450.

Referring to FIG. 3, after a spacer 320 is formed on the electron injection layer 450 at a position corresponding to the pixel definition layer 350, and the sealant 340 and the moisture absorbent 330 are formed on the gate insulating layer 140 in the peripheral area PA. Then, the display substrate 100 and the encapsulation substrate 200 are bonded to each other. The bonding between the display substrate 100 and the encapsulation substrate 200 is performed by the sealant 340.

As described above, according to the present exemplary embodiment, as the surface of the gate insulating layer 140 is uniformly formed, the spaces do not exist between the sealant 340 and the gate insulating layer 140 and between the moisture absorbent 330 and the gate insulating layer 140.

Accordingly, the bonding between the sealant 340 and the gate insulating layer 140 and between the moisture absorbent 330 and the gate insulating layer 140 is easily performed to prevent external moisture or foreign particles from permeating into the display area DA.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A manufacturing method of an organic light emitting diode display device, comprising:
forming a gate electrode on a display area of a substrate comprising a peripheral area surrounding the display area;
forming a gate insulating layer by depositing an inorganic insulating material on the gate electrode and the substrate;
forming a semiconductor layer on the gate insulating layer in the display area, the semiconductor layer overlapping the gate electrode;
forming source and drain electrodes on the semiconductor layer;
forming a passivation layer on the source electrode, the drain electrode, and the gate insulating layer;
forming a first electrode on the passivation layer and connected to the drain electrode;
forming an etching preventing layer on the gate insulating layer in the peripheral area;
forming a pixel definition layer on the passivation layer and the first electrode, the pixel definition layer comprising an opening exposing a portion of the first electrode;
forming a first organic layer on exposed portion of the first electrode and a second organic layer on the pixel definition layer and the etching preventing layer;
removing the second organic layer from the etching prevention layer;
removing the etching prevention layer; and
forming a second electrode on the first organic layer, the second organic layer, and the pixel definition layer.

2. The method of claim 1, wherein the first electrode and the etching preventing layer are simultaneously formed.

3. The method of claim 2, wherein the first electrode and the etching preventing layer are formed of the same material.

4. The method of claim 3, wherein:
the first organic layer comprises emission layers; and
the second organic layer comprises a hole injection layer, a hole transporting layer, an electron transporting layer, and an electron injection layer.

5. The method of claim 4, wherein forming the first and second organic layers comprises forming the first and second organic layers by transmitting organic materials through masks onto the substrate, while the substrate is moved relative to the masks.

6. The method of claim 5, wherein the masks comprise first, second, third, fourth, fifth, sixth, and seventh masks that are sequentially arranged.

7. The method of claim 6, wherein:
the first, second, sixth, and seventh masks respectively include first, second, sixth, and seventh transmissive portions; and
the third, fourth, and fifth masks respectively include third, fourth, and fifth transmissive portions.

8. The method of claim 7, wherein the first, second, sixth, and seventh transmissive portions are located at the same positions on the respective masks.

9. The method of claim 8, wherein the third, fourth, and fifth transmissive portions are located at different positions on the respective masks.

10. The method of claim 9, wherein the first mask transmits a material of the hole injection layer through the first transmissive portion,
the second mask transmits a material of the hole transporting layer through the second transmissive portion,
the third, fourth, and fifth masks respectively transmit materials of the emission layers through the third, fourth, and fifth transmissive portions,
the sixth mask transmits a material of the electron transporting layer through the sixth transmissive portion, and
the seventh mask transmits a material of the electron injection layer through the seventh transmissive portion.

11. The method of claim 10, wherein the forming of the first organic layer comprises sequentially forming the hole injection layer, the hole transporting layer, the emission layers, the electron transporting layer, and the electron injection layer, and
the forming of the second organic layer comprises forming the emission layers between the hole transporting layer and the electron transporting layer.

12. The method of claim 1, further comprising:
forming a spacer on the second electrode at a position corresponding to the pixel definition layer;
forming a sealant and a moisture absorbent on the gate insulating layer in the peripheral area; and
bonding an encapsulation substrate to the sealant.

13. The method of claim 12, wherein the moisture absorbent is formed between the sealant and the display area.

14. The method of claim 1, wherein the first electrode and the etching preventing layer are formed of different materials.

15. A manufacturing method of an organic light emitting diode display device, comprising:
forming a gate electrode on a display area of a substrate comprising a peripheral area surrounding the display area;
forming a gate insulating layer by depositing an inorganic insulating material on the gate electrode and the substrate;
forming a semiconductor layer on the gate insulating layer in the display area, the semiconductor layer overlapping the gate electrode;
forming a passivation layer on the semiconductor layer;
forming a first electrode on the passivation layer and connected to the semiconductor layer;
forming an etching preventing layer on the gate insulating layer in the peripheral area;
forming a pixel definition layer on the passivation layer, the pixel definition layer comprising an opening exposing the first electrode;
forming an organic layer on the pixel definition layer and the etching preventing layer;
removing the organic layer from the etching prevention layer;
removing the etching prevention layer to expose the gate insulating layer; and
forming a sealant and a moisture absorbent on the exposed portion of the gate insulating layer.

16. The method of claim 15, wherein the first electrode and the etching preventing layer are formed from the same layer of material.

17. The method of claim 2, wherein:
the organic layer comprises a hole injection layer, a hole transporting layer, emission layers, an electron transporting layer, and an electron injection layer, the emission layers being disposed in openings of the pixel definition layer and between the electron transporting layer and the hole transporting layer; and
the forming of the organic layer comprises using seven masks that are disposed side by side and that are moved with respect to the substrate, to deposit materials of the organic layer.

18. The method of claim 17, wherein:
four of the masks are used to form the hole injection layer, the hole transporting layer, the electron transporting layer, and the electron injection layer; and
three of the masks are used to form the emission layers.
